(19) United States
(12) Patent Application Publication
(10) Pub. No.: US 2010/0133600 A1
(43) Pub. Date: Jun. 3, 2010

(54) Semiconductor devices having increased sensing margin

(75) Inventors: Won-joo Kim, Hwaseong-si (KR); Sang-moo Choi, Yongin-si (KR); Tae-hee Lee, Yongin-si (KR); Yoon-dong Park, Yongin-si (KR); Dae-kil Cha, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,686

(22) Filed: Nov. 30, 2009

(30) Foreign Application Priority Data
Dec. 1, 2008 (KR) 10-2008-0120681

(51) Int. Cl. H01L 29/788; H01L 21/28

(52) U.S. Cl. 257/316; 438/593; 257/E29.3; 257/E21.209

(57) ABSTRACT

One transistor (1-T) dynamic random access memories (DRAM) having improved sensing margins that are relatively independent of the amount of carriers stored in a body region thereof.

### CROSS-REFERENCE TO RELATED APPLICATIONS

This application claims priority under 35 U.S.C. §119 to Korean Patent Application No. 10-2008-0120681, filed on Dec. 1, 2008, in the Korean Intellectual Property Office (KIPO), the contents of which is incorporated herein in its entirety by reference.

### BACKGROUND

1. Field

Example embodiments of the inventive concepts relate to semiconductor memory devices, and more particularly, to semiconductor memory devices (e.g., a 1-transistor (T) dynamic random access memory (DRAM)) with improved sensing margin.

2. Description of the Related Art

A 1-T DRAM including a single transistor and no capacitor has recently become popular. 1-T DRAMs are not only simple to manufacture but also have a better sensing margin.

However, A 1-T DRAM may need to be manufactured on a silicon-on-insulator (SOI) wafer, thereby increasing manufacturing costs. Also, because the physical properties of SOI wafers have not been fully established yet, 1-T DRAMs should be manufactured in an embedded form rather than a stand-alone form.

### SUMMARY

Example embodiments of the inventive concepts provide semiconductor memory devices in which a capacitance of a gate stack is reduced and/or improved in order to increase and/or improve a sensing margin, and the dielectric region may be relatively thick to reduce and/or improve the capacitance.

According to an aspect of the inventive concepts, there is provided a 1-transistor dynamic random access memory (1-T DRAM) including a substrate region; an insulating region on the substrate region; a body region on the insulating region, the body region configured to store carriers; a first dielectric region on the body region; a first floating gate pattern on the first dielectric region; a second dielectric region on the first floating gate pattern; and a control gate pattern on the second dielectric region, the control gate pattern configured to control an amount of carriers stored in the body region.

According to another aspect of the inventive concepts, there is provided a 1-transistor dynamic random access memory (1-T DRAM) including a substrate region; an insulating region on the substrate region; a body region on the insulating region, the body region configured to store carriers; a plurality of dielectric regions on the body region; and a control gate pattern on the plurality of dielectric regions, the control gate pattern configured to control an amount of carriers stored in the body region.

According to another aspect of the inventive concepts, there is provided a 1-transistor dynamic random access memory (1-T DRAM) including a substrate region; an insulating region on the substrate region; a body region on the insulating region, the body region configured to store carriers; a dielectric region on the body region, a thickness of the dielectric region determined according to a design rule value applied to the 1-T DRAM; and a control gate pattern on the dielectric region, the control gate pattern configured to control an amount of carriers stored in the body region.

According to another aspect of the inventive concepts, there is provided a method of improving a sensing margin of a one transistor dynamic random access memory (1-T DRAM), the method including establishing a thickness of at least one region of a gate stack of a 1-T DRAM cell such that a capacitance of the gate stack corresponds to a desired sensing margin, the gate stack including a first dielectric region, a floating gate pattern region and a second dielectric region.

### BRIEF DESCRIPTION OF THE DRAWINGS

Example embodiments of the inventive concepts will be more clearly understood from the following brief description taken in conjunction with the accompanying drawings. FIGS. 1-16 represent non-limiting, example embodiments as described herein.

FIG. 1 is a cross-sectional diagram of an example 1-transistor (1-T) dynamic random access memory (DRAM);

FIG. 2 is a circuit diagram of the 1-T DRAM of FIG. 1;

FIG. 3 is a cross-sectional diagram illustrating a WRITE mode in which a plurality of carriers are generated in the 1-T DRAM of FIG. 1;

FIG. 4 is a cross-sectional diagram illustrating a HOLD mode in which carriers are stored after the WRITE mode of FIG. 3;

FIG. 5 is a cross-sectional diagram illustrating a state in which carriers are not stored;

FIG. 6 is a graph illustrating a sensing margin of the 1-T DRAM of FIG. 1;

FIG. 7 is a cross-sectional diagram of a 1-T DRAM according to an example embodiment of the inventive concepts;

FIG. 8 is a cross-sectional diagram illustrating capacitances, between a control gate pattern and a first floating gate pattern and between the first floating gate pattern and a body region, of the 1-T DRAM of FIG.7;

FIG. 9 is a cross-sectional diagram of a 1-T DRAM according to a comparative example;

FIG. 10 is a cross-sectional diagram illustrating capacitance between a control gate pattern and a body region of the 1-T DRAM of FIG. 9;

FIGS. 11A and 11B are graphs illustrating sensing margins of a 1-T DRAM;

FIG. 12 is a graph comparing a sensing margin of the 1-T DRAM of FIG. 7 with a sensing margin of the 1-T DRAM of FIG. 9;

FIG. 13 is a cross-sectional diagram of a 1-T DRAM according to an example embodiment of the inventive concepts;

FIG. 14 is a cross-sectional diagram of a 1-T DRAM according to an example embodiment of the inventive concepts;

FIG. 15 is a chart showing a thickness of a dielectric region according to design rule values applied to a 1-T DRAM; and

FIG. 16 is a graph illustrating a sensing margin of the 1-T DRAM of FIG. 14 varying as a function of the thickness of a dielectric region therein.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

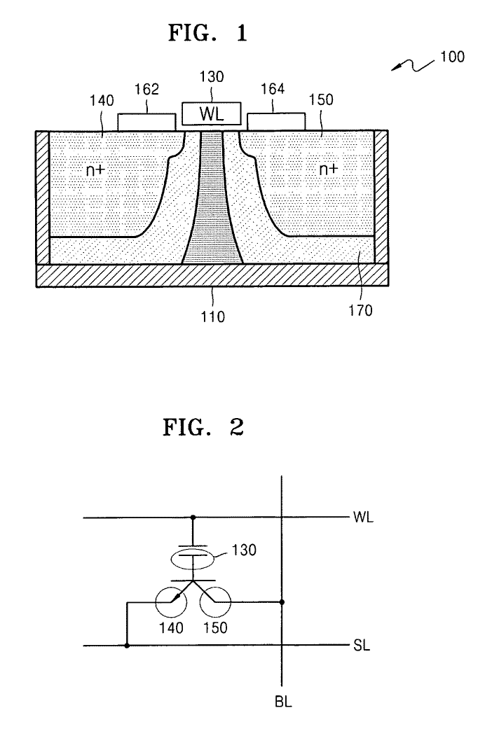

FIG. 1 is a cross-sectional diagram of an example 1-transistor (1-T) dynamic random access memory (DRAM). Referring to FIG. 1, the 1-T DRAM may include a semiconductor substrate 110, a gate pattern 130, a source region 140, a drain region 150, a source electrode 162, a drain electrode 164, and a body region 170. The source region 140 and the drain region 150 may be doped with impurities. The source region 140 and the drain region 150 may switch functions. The source electrode 162 may become the drain electrode and the drain electrode 164 may become the source electrode.

It may be possible to write data to, or erase or read data from, the 1-T DRAM of FIG. 1 by adjusting a gate voltage, a drain voltage, and a source voltage that are respectively applied to the gate pattern 130, the drain electrode 164, and the source electrode 162.

FIG. 2 is a circuit diagram of the 1-T DRAM of FIG. 1. Referring to FIG. 2, the source region 140 may be connected to a source line SL and the drain region 150 may be connected to a bit line BL. A source voltage may be applied to the source region 140 via the source line SL and a drain voltage may be applied to the drain region 150 via the bit line BL. The gate pattern 130 may be connected to a word line WL, and a gate voltage may be applied to the gate pattern 130 via the word line WL.

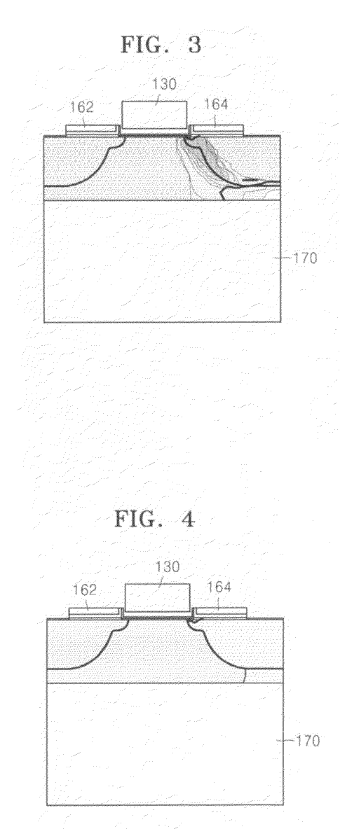

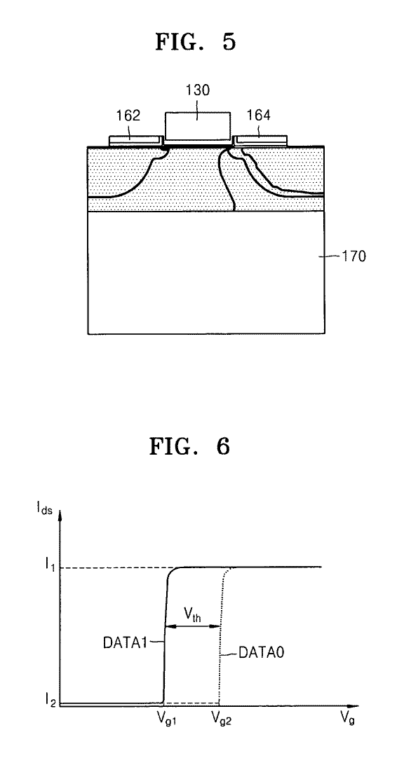

FIG. 3 is a cross-sectional diagram illustrating a WRITE mode in which a plurality of carriers are generated in the 1-T DRAM of FIG. 1. FIG. 4 is a cross-sectional diagram illustrating a HOLD mode in which carriers are stored after the WRITE mode of FIG. 3. FIG. 5 is a cross-sectional diagram illustrating a state in which carriers are not stored. In the WRITE mode, a plurality of carriers (e.g., holes) may be generated at an interface between the body region 170 and the drain region 150, due to impact ionization, as illustrated in FIG. 3. The generated carriers may be stored in the body region 170 (HOLD mode) as illustrated in FIG. 4. If carriers are stored in the body region 170, it may be considered that a data ‘1’ is written to the 1-T DRAM. If carriers are not generated in the WRITE mode, no (and/or relatively few) carriers may be stored in the body region 170 as illustrated in FIG. 5. If carriers are not stored in the body region 170, it may be considered that a data ‘0’ is written to the 1-T DRAM. Carriers may be removed from the body region 170 in an ERASE mode. The state of the body region 170 after the ERASE mode is illustrated in FIG. 5.

In a READ mode, it may be possible to read data from the 1-T DRAM by measuring the amount of current that flows from the source region 140 to the drain region 150. If a large and/or increased amount of carriers are stored in the body region 170, a large and/or increased amount of current may flow from the source region 140 to the drain region 150. If a small and/or decreased amount of carriers are stored in the body region 170, a small and/or decreased amount of current may flow from the source region 140 to the drain region 150.

FIG. 6 is a graph illustrating a sensing margin of the 1-T DRAM of FIG. 1. Referring to FIG. 6, when a data ‘1’ is written to the 1-T DRAM, (e.g., when carriers are stored in the body region 170) the amount of sensing current according to a gate voltage applied to the gate pattern 130 may be illustrated as a plot DATA1. When data ‘0’ is written to the 1-T DRAM (e.g., when carriers are not stored in the body region 170) the amount of sensing current according to the gate voltage applied to the gate pattern 130 may be illustrated as a plot DATA0. If any voltage between a first gate voltage V_{g1} and a second gate voltage V_{g2} is applied to the gate pattern 130, a large and/or increased amount of current I₁ may flow when a data ‘1’ is written to the 1-T DRAM and a small and/or decreased amount of current I₂ may flow when a data ‘0’ is written to the 1-T DRAM. Accordingly, it may be possible to determine whether data written to the 1-T DRAM is ‘1’ or ‘0’. The difference between the first gate voltage V_{g1} and the second gate voltage V_{g2} may be referred to as a ‘sensing margin’ (e.g., indicated by ‘ΔVth’).

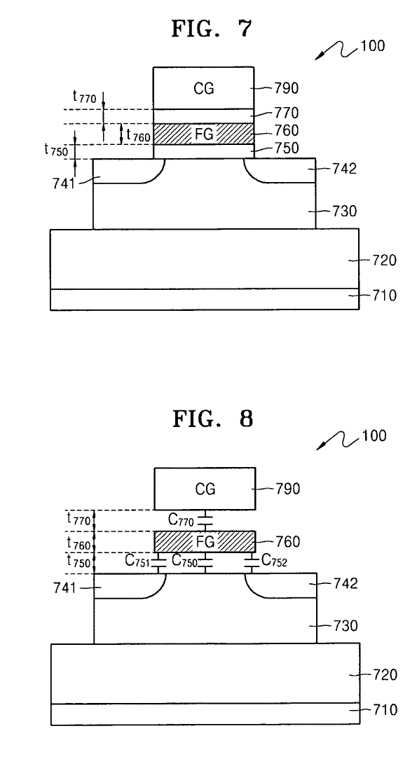

FIG. 7 is a cross-sectional diagram of a 1-T DRAM 100 according to an example embodiment of the inventive concepts. Referring to FIG. 7, the 1-T DRAM 100 of the present example embodiment may include a semiconductor substrate 710, an insulating region 720, a body region 730, a first source/drain region 741, a second source/drain region 742, a first dielectric region 750, a floating gate pattern 760, a second dielectric region 770, and a control gate pattern 790. The insulating region 720 may be on the semiconductor substrate 710. The body region 730 may be on the insulating region 720 and may store carriers. When a voltage is applied to the control gate pattern 790, carriers may be generated and stored in the body region 730. The data state of the 1-T DRAM may be determined by the amount of carriers stored in the body region 730 (e.g., according to FIGS. 3-5). The first dielectric region 750, the floating gate pattern 760 and the second dielectric region 770 may be on the body region 730 (e.g., sequentially formed on the body region 730). The control gate pattern 790 may be on the second dielectric region 770. The thicknesses t₇₅₀, t₇₆₀ and t₇₇₀ may be the thicknesses of the first dielectric region 750, the floating gate pattern 760 and the second dielectric region 770, respectively.

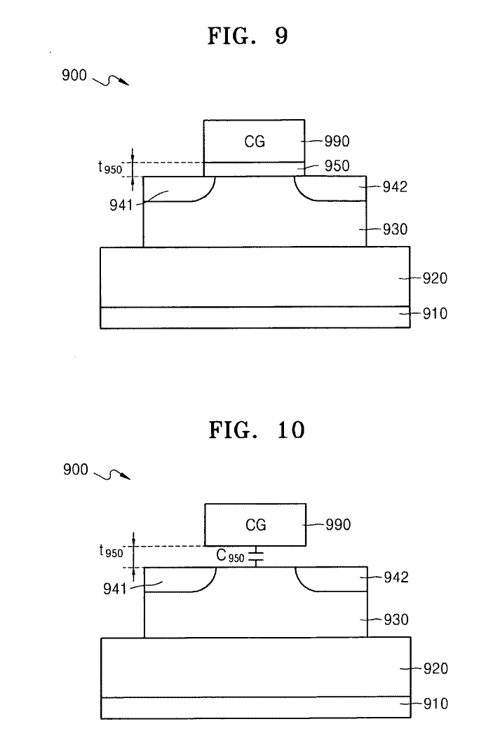

FIG. 8 is a cross-sectional diagram illustrating capacitances, between the control gate pattern 790 and the first floating gate pattern 760 and between the first floating gate pattern 760 and the body region 730, of the 1-T DRAM of FIG. 7. Referring to FIGS. 7 and 8, three regions (e.g., the first dielectric region 750, the floating gate pattern 760, and the second dielectric region 770) may be disposed between the body region 730 and the control gate pattern 790. In the 1-T DRAM 100 of FIG. 7, the distance between the body region 730 and the control gate pattern 790 may be greater compared to when only one region is disposed between a body region and a control gate pattern, for example, as illustrated in FIG. 9. A comparison between the 1-T DRAM 100 of FIG. 7 and a comparative example thereof will later be provided with reference to FIG. 9. In the current example embodiment, the capacitance between the body region 730 and the control gate pattern 790 may be lowered, increasing and/or improving the sensing margin of the 1-T DRAM. As described below, the sensing margin of the 1-T DRAM may be increased without having to increase the amount of carriers to be generated and stored in the body region 730.

Equation (1) shows the relationship between a voltage V_{FG} between the first floating gate pattern 760 and the body region 730 and a voltage V_{CG} between the control gate pattern 790 and the body region 730. The voltages V_{FG} and V_{CG} may be expressed using capacitance (C₇₅₀+C₇₅₁+C₇₅₂) between the first floating gate pattern 760 and the body region 730 and capacitance C₇₇₀ between the control gate pattern 790 and the floating gate pattern 760.

V_{FG}=V_{CG}*γ

γ=C770/(C750+C751+C752+C770) (1)

where V_{FG} denotes the voltage between the first floating gate pattern 760 and the body region 730, and V_{CG} denotes the voltage between the control gate pattern 790 and the body region 730.

One of the thicknesses t₇₅₀, t₇₆₀, and t₇₇₀ of the first dielectric region 750, the floating gate pattern 760, and the second dielectric region 770 may be adjusted. If the thickness t₇₇₀ of the second dielectric region 770 is changed, the capacitance C₇₇₀ between the control gate pattern 790 and the first floating gate pattern 760 may change accordingly. If the thickness t₇₅₀ of the first dielectric region 750 is changed, the capacitance (C₇₅₀+C₇₅₁+C₇₅₂) between the first floating gate pattern 760 and the body region 730 may change accordingly. A change in the capacitance C₇₇₀ or the capacitance (C₇₅₀+C₇₅₁+C₇₅₂) between the first floating gate pattern 760 and the body region 730 may result in a change in the capacitance between the control gate pattern 790 and the body region 730.

The sensing margin of the 1-T DRAM may be proportional to the amount of carriers stored in the body region 730 but inversely proportional to the capacitance between the control gate pattern 790 and the body region 730. If the capacitance between the control gate pattern 790 and the body region 730 decreases, the sensing margin of the 1-T DRAM may increase. It may be possible to increase the sensing margin of the 1-T DRAM 100 of FIG. 7 by, for example, increasing one of the thicknesses t₇₅₀, t₇₆₀, and t₇₇₀ of the first dielectric region 750, the first floating gate pattern 760, and the second dielectric region 770.

FIG. 9 is a cross-sectional diagram illustrating a 1-T DRAM 900 according to a comparative example. FIG. 10 is a cross-sectional diagram illustrating a capacitance C₉₅₀ between a control gate pattern 990 and a body region 930 in the 1-T DRAM of FIG. 9. Referring to FIGS. 9 and 10, the 1-T DRAM 900 may include a substrate 910, an insulating layer 920, a first source/drain region 941, a second source/drain region 942, a body region 930, a dielectric region 950 and a control gate pattern 990.

Referring to FIGS. 7, 9 and 10, according to the 1-T DRAM 900, only one dielectric region 950 may be disposed between the control gate pattern 990 and the body region 930, whereas three regions (the first dielectric region 750, the floating gate pattern 760, and the second dielectric region 770) may be disposed between the body region 730 and the control gate pattern 790 in the 1-T DRAM 100 of FIG. 7. The distance between the control gate pattern 790 and the body region 730 in the 1-T DRAM 100 of FIG. 7 may be greater than that between the control gate pattern 990 and the body region 930 (e.g., thickness t₉₅₀) in the 1-T DRAM 900 of FIG. 9. The sensing margin of the 1-T DRAM 100 of FIG. 7 may be greater than that of the 1-T DRAM 900 of FIG. 9 because the capacitance between the control gate pattern 790 and the body region 730 in the 1-T DRAM 100 of FIG. 7 may be less than that between the control gate pattern 990 and the body region 930 in the 1-T DRAM 900 of FIG. 9.

According to example embodiments of the inventive concepts, the 1-T DRAM 100 of FIG. 7 may have three regions (e.g., the first dielectric region 750, the floating gate pattern 760, and the second dielectric region 770) and the sensing margin of the 1-T DRAM of FIG. 7 may be greater than the 1-T DRAM of FIG. 9 without having to adjust the thicknesses t₇₅₀-t₇₇₀ of these regions. Note that only one dielectric region (e.g., the dielectric region 950) may be included in the comparative example of FIG. 9.

The 1-T DRAM 100 of FIG. 7 may be modified according to example embodiments of the inventive concepts. Although not shown in the drawings, a third dielectric region, a second floating gate pattern and a fourth dielectric region may further be added between the control gate pattern 790 and the body region 730, in addition to the first dielectric region 750, the floating gate pattern 760, and the second dielectric region 770. In this case, the capacitance between the control gate pattern 790 and the body region 730 may be further reduced, thereby further improving the sensing margin of the 1-T DRAM.

According to example embodiments, one of the third and fourth dielectric regions may be omitted. For example, the first dielectric region 750, the floating gate pattern 760, the second dielectric region 770, the third dielectric region, and the second floating gate pattern may be on the body region 730 (e.g., sequentially formed on the body region 730). The total number of dielectric regions and floating gate patterns that may be present between the control gate pattern 790 and the body region 730 is not limited.

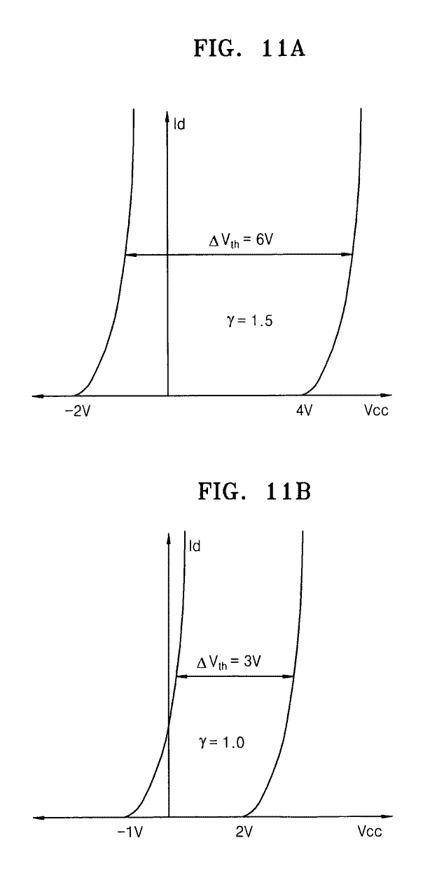

FIGS. 11A and 11B are graphs illustrating sensing margins of a 1-T DRAM. FIG. 11A is a graph illustrating a 6V sensing margin of a 1-T DRAM corresponding to γ=1.5 according to equation 1. FIG. 11B is a graph illustrating a 3V sensing margin of a 1-T DRAM corresponding to γ=1.0 according to equation 1. For example, the sensing margin of the 1-T DRAM 100 of FIG. 7 may be adjusted to about 6V from about 3V by lowering the capacitance between the first dielectric region 750 and the first floating gate pattern 760. For example, by increasing the thickness t₇₅₀ of the first dielectric region 750. The sensing margin of the 1-T DRAM 100 of FIG. 7 may be reduced to 3V from 6V by increasing the capacitance between the first dielectric region 750 and the first floating gate pattern 760. For example, by reducing the thickness t₇₅₀ of the first dielectric region 750. One having ordinary skill in the art will understand that a sensing margin may be adjusted by changing any parameter affecting capacitance between the control gate pattern 790 and the floating body region 730.

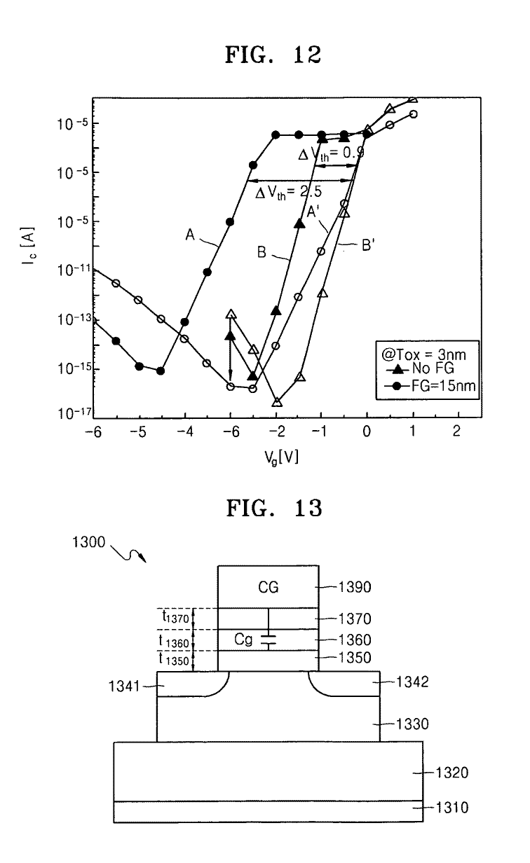

FIG. 12 is a graph comparing a sensing margin of the 1-T DRAM 100 of FIG. 7 with a sensing margin of the 1-T DRAM 900 of FIG. 9. In FIG. 12, plots A and A′ illustrate voltage-current characteristics of the 1-T DRAM 100 of FIG. 7, and plots B and B′ illustrate voltage-current characteristics of the 1-T DRAM 900 of FIG. 9. Referring to FIG. 12, the sensing margin of the 1-T DRAM 100 of FIG. 7 may be about 2.5 V and the sensing margin of the comparative example of FIG. 9 may be about 0.9 V. That is, the sensing margin of the 1-T DRAM 100 of FIG. 7 is greater than that of the comparative example of FIG. 9.

FIG. 13 is a cross-sectional diagram of a 1-T DRAM 1300 according to an example embodiment of the inventive concepts. Referring to FIG. 13, the 1-T DRAM 1300 may include a semiconductor substrate 1310, an insulating region 1320, a body region 1330, a first source/drain region 1341, a second source/drain region 1342, a first dielectric region 1350, a second dielectric region 1360, a third dielectric region 1370, and a control gate pattern 1390.

Referring to FIG. 13, three dielectric regions (e.g., first through third dielectric regions 1350-1370) may be disposed between the body region 1330 and the control gate pattern 1390. Although according to the present example embodiment three dielectric regions are described, the total number of dielectric regions is not limited. Because the first through third dielectric regions 1350-1370 may be disposed between the body region 1330 and the control gate pattern 1390 as described above, the distance between the control gate pattern 1390 and the body region 1330 may be greater than when only one dielectric region is present as illustrated in FIG. 9. According to the 1-T DRAM 1300, a capacitor representing a capacitance Cg between the control gate pattern 1390 and the body region 1330 may be lowered, thereby increasing the sensing margin of the 1-T DRAM 1300. At least one of the thicknesses t₁₃₅₀, t₁₃₆₀, and t₁₃₇₀ of the first to third dielectric regions 1350-1370 of FIG. 13 may be adjusted, thereby controlling the sensing margin of the 1-T DRAM 1300.

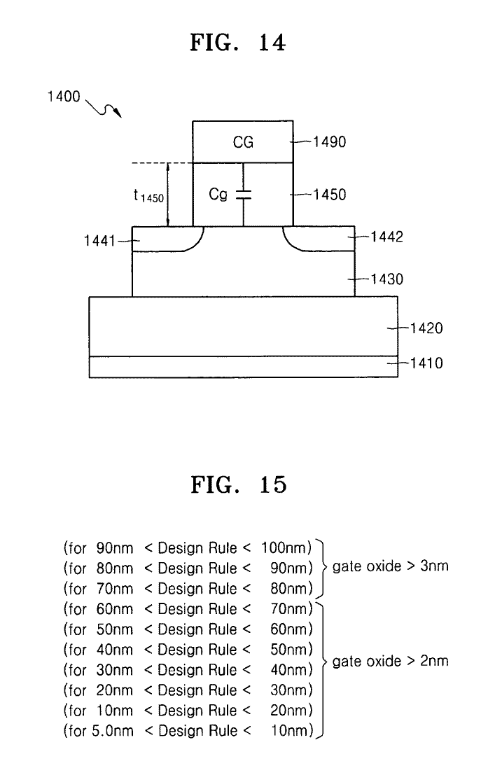

FIG. 14 is a cross-sectional diagram of a 1-T DRAM 1400 according to an example embodiment of the inventive concepts. Referring to FIG. 14, the 1-T DRAM 1400 of the present embodiment may include a semiconductor substrate 1410, an insulating region 1420, a body region 1430, a first source/drain region 1441, a second source/drain region 1442, a dielectric region 1450, and a control gate pattern 1490. The thickness t₁₄₅₀ of the dielectric region 1450 may be greater than that of a general dielectric region. The thickness of the dielectric region 1450 may be greater than that of dielectric regions illustrated in FIGS. 7, 9 and 13. For example, the thickness of the dielectric region 1450 may be greater than that of the first dielectric region 1350 illustrated in FIG. 13.

The distance (e.g., thickness t₁₄₅₀) between the control gate pattern 1490 and the body region 1430 may increase by forming the dielectric region 1450 to have a greater thickness than the dielectric region 950 of the 1-T DRAM 900 of FIG. 9. The sensing margin of the 1-T DRAM 1400 may be increased by lowering the capacitance Cg between the control gate pattern 1490 and the body region 1430. The sensing margin of the 1-T DRAM 1400 may be increased by forming only one dielectric region, the dielectric region 1450. The thickness of the dielectric region 1450 may be determined such that the capacitance between the control gate pattern 1490 and the body region 1430 is less than or equal to a threshold.

FIG. 15 is a chart showing the thickness of a dielectric region according to design rule values applied to a 1-T DRAM. For example, the thickness t₁₄₅₀ of the dielectric region 1450 of FIG. 14 may vary according to design rule values applied to the 1-T DRAM. Referring to FIG. 15, if the design rule value is greater than 70 nm and less than 100 nm, then the thickness t₁₄₅₀ of the dielectric region 1450 may be greater than about 3 nm. If the design rule value is not greater than 70 nm, then the thickness t₁₄₅₀ of the dielectric region 1450 may be greater than about 2 nm. FIG. 15 provides an example of the thickness of a dielectric region according to design rule values. The thickness t₁₄₅₀ of the dielectric region 1450 may have different values corresponding to the respective ranges of the design rule, rather than as illustrated in FIG. 15. The thickness t₁₄₅₀ of the dielectric region 1450 may have values other than about 2 nm and about 3 nm, according to design rule values. Design rule values may be categorized into a plurality of ranges other than those shown in FIG. 15. For example, the differences between the ranges of the design rule values may be 5 nm.

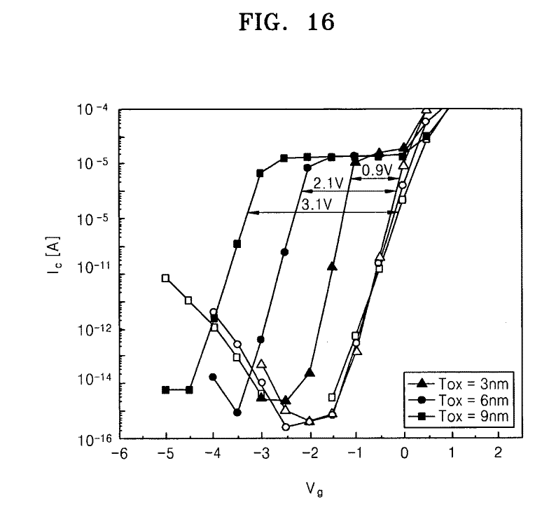

FIG. 16 is a graph illustrating a sensing margin of the 1-T DRAM of FIG. 14 varying as a function of the thickness of a dielectric region therein. Referring to FIG. 16, the thickness of the dielectric region may be about 3 nm, 6 nm and 9 nm, and the sensing margin of the 1-T DRAM may be about 0.9 V, 2.1 V and 3.1 V, respectively.

While the inventive concepts are particularly shown and described with reference to example embodiments thereof, it will be understood by one of ordinary skill in the art that various changes in form and detail may be made therein without departing from the spirit and scope of the claims.

What is claimed is:

1. A 1-transistor dynamic random access memory (1-T DRAM) comprising:
a substrate region;
an insulating region on the substrate region;
a body region on the insulating region, the body region configured to store carriers;
a first dielectric region on the body region;
a first floating gate pattern on the first dielectric region;
a second dielectric region on the first floating gate pattern; and
a control gate pattern on the second dielectric region, the control gate pattern configured to control an amount of the carriers stored in the body region.

2. The 1-T DRAM of claim 1, wherein at least one of the first dielectric region, the first floating gate pattern and the second dielectric region has a thickness such that a desired capacitance exists between the control gate pattern and the body region.

3. The 1-T DRAM of claim 2, wherein the desired capacitance provides a sensing margin of greater than about 0.9V.

4. The 1-T DRAM of claim 3, wherein the desired capacitance provides a sensing margin of about 2.5V.

5. The 1-T DRAM of claim 2, wherein the thickness of the first and second dielectric regions is about 3 nm, and
the thickness of the first floating gate pattern is about 15 nm.

6. The 1-T DRAM of claim 1, wherein a data state of the 1-T DRAM is determined by the amount of the carriers stored in the body region.

7. The 1-T DRAM of claim 1, wherein the carriers stored in the body region are one of holes and electrons.

8. The 1-T DRAM of claim 1, further comprising:
a third dielectric region on the second dielectric region;
a second floating gate pattern on the third dielectric region; and
a fourth dielectric region on the second floating gate pattern,
wherein the control gate pattern is on the fourth dielectric region.

9. The 1-T DRAM of claim 8, wherein at least one of the first dielectric region, the first floating gate pattern, the second dielectric region, the third dielectric region, the second floating gate pattern and the fourth dielectric region has a thickness such that a desired capacitance exists between the control gate pattern and the body region.

10. The 1-T DRAM of claim 1, further comprising:
a second floating gate pattern on the second dielectric region; and
a third dielectric region on the second floating gate pattern,
wherein the control gate pattern is on the third dielectric region.

11. A 1-transistor dynamic random access memory (1-T DRAM) comprising:
a substrate region;
an insulating region on the substrate region;
a body region on the insulating region, the body region configured to store carriers;
a dielectric region on the body region; and
a control gate pattern on the dielectric region, the control gate pattern configured to control an amount of the carriers stored in the body region.

12. The 1-T DRAM of claim 11, wherein the dielectric region includes a plurality of dielectric layers on the body region.

13. The 1-T DRAM of claim 12, wherein least one of the plurality of dielectric layers has a thickness such that a desired capacitance exists between the control gate pattern and the body region.

14. The 1-T DRAM of claim 13, wherein a sum of thicknesses of the plurality of dielectric regions is determined according to a design rule value applied to the 1-T DRAM.

15. The 1-T DRAM of claim 11, wherein a thickness of the dielectric region is determined according to a design rule value applied to the 1-T DRAM.

16. The 1-T DRAM of claim 15, wherein the thickness of the dielectric region is proportional to the design rule value.

17. The 1-T DRAM of claim 16, wherein the thickness of the dielectric region is determined such that a capacitance between the control gate pattern and the body region is less than or equal to a threshold.

18. A method of improving a sensing margin of a one transistor dynamic random access memory (1-T DRAM), the method comprising:
establishing a thickness of at least one region of a gate stack of a 1-T DRAM cell such that a capacitance of the gate stack corresponds to a desired sensing margin, the gate stack including a first dielectric region, a floating gate pattern region and a second dielectric region.

19. The method of claim 18, wherein the establishing step varies the thickness of the at least one region of the gate stack according to a design rule value applied to the cell of the 1-T DRAM.

20. The method of claim 18, wherein the establishing step increases the sensing margin by increasing the thickness of the at least one region.
